(19) United States
(12) Patent Application Publication
(10) Pub. No.: US 2001/0025994 A1
(43) Pub. Date: Oct. 4, 2001

(54) Process for producing semiconductor device and semiconductor device

(76) Inventors: Kazuhiko Yoshino, Tenri-shi (JP); Narakazu Shimomura, Gojo-shi (JP); Satoshi Hikida, Yamabe-gun (JP)

Correspondence Address: NIXON & VANDERHYE P.C., 8th Floor, 1100 North Glebe Rd., Arlington, VA, 22201-4714, US

(21) Appl. No.: 09/766,613

(22) Filed: Jan. 23, 2001

(30) Foreign Application Priority Data
Mar. 23, 2000 (JP) 2000-082365

(51) Int. Cl. H01L 21/8238; H01L 29/94; H01L 31/119; H01L 29/76; H01L 31/062

(52) U.S. Cl. 257/369; 438/199

(57) ABSTRACT

A process for producing a semiconductor device comprises the steps of: (a) forming a gate electrode on N channel and P channel transistors forming regions (N-Tr region and P-Tr region) on a semiconductor substrate; (b) forming a side wall spacer on a side wall of the gate electrode; (c) covering the P-Tr region with a resist, and forming a source/drain region on the N-Tr region by ion implantation using the resist, the gate electrode and the side wall spacer as a mask; (d) removing a part of the side wall spacer of the gate electrode in the N-Tr region; (e) forming an LDD region on the N-Tr region by ion implantation using the resist, the gate electrode and the resulting side wall spacer as a mask; (f) removing the resist; (g) covering the N-Tr region with a resist, and forming a source/drain region on the P-Tr region by ion implantation using the resist, the gate electrode and the side wall spacer as a mask; (h) removing a part of the side wall spacer of the gate electrode in the P-Tr region; and (i) forming an LDD region on the P-Tr region by ion implantation using the resist, the gate electrode and the resulting side wall spacer as a mask.

### CROSS-REFERENCE TO RELATED APPLICATION

This application is related to Japanese application No. 2000-82365 filed on Mar. 23, 2000, whose priority is claimed under 35 USC § 119, the disclosure of which is incorporated by reference in its entirety.

### FIELD OF THE INVENTION

The present invention relates to a process for producing a semiconductor device and a semiconductor device, and more particularly it relates to a process for producing a semiconductor device and a semiconductor device that are excellent in hot carrier resistance and have a suppressed short channel effect.

### BACKGROUND OF THE INVENTION

A conventional MOS transistor generally has an LDD (lightly doped drain) region for improving hot carrier resistance, and utilizes such a structure that has an impurity layer (hereinafter referred to as a pocket layer) having a conductive type different from a source/drain region between the LDD region and a channel region.

A process for producing a CMOS transistor having an LDD layer and a pocket layer will be described below.

As shown in FIG. 4A, after conducting ion implantation for Vth adjustment on a semiconductor substrate 21 having an element isolation region 22, a pretreatment such as RCA cleaning, is conducted. Thereafter, a gate dielectric film 23 is formed by thermal oxidation, and a polysilicon film is deposited thereon. The polysilicon film is patterned to a desired form to form a gate electrode 24 and a part of wiring (not shown in the figure).

As shown in FIG. 4B, a P channel transistor forming region is covered with a resist 25, and ion implantation of an N type impurity is conducted on an N channel transistor forming region at an implantation angle of from the normal line (hereinafter simply referred to as 0°), so as to form an LDD region 26. A P type impurity is then ion-implanted at an implantation angle of from 30 to 40° from the normal line (hereinafter simply referred to as from 30 to 40°), so as to form a pocket layer 27.

As shown in FIG. 4C, after removing the resist 25, the N channel transistor forming region is covered with a resist 28, and an LDD region 29 and a pocket layer 30 are formed on the P channel transistor forming region in the same manner as in the foregoing.

As shown in FIG. 4D, an HTO (high temperature oxide) film is deposited on the resulting semiconductor substrate 21, and the whole surface is subjected to etch back, so as to form a side wall spacer 31 is formed on a side wall of the gate electrode.

As shown in FIG. 4E, after covering the P channel transistor forming region with a resist 32, ion implantation of an N type impurity is conducted to the N channel transistor forming region at an implantation angle of 7°, so as to form a high concentration source/drain region 33.

As shown in FIG. 4F, after covering the N channel transistor forming region with a resist 34, a high concentration source/drain region 34 is formed in the same manner as in the foregoing.

Thereafter, the N type and P type impurities are activated by conducting a thermal treatment according to a known method, and further, an interlayer insulating film, a contact hole and a wiring pattern are formed to complete the semiconductor device.

Another process for producing a CMOS transistor having an LDD layer and a pocket layer will be described below.

As shown in FIG. 5A, after forming a gate electrode 41 on a semiconductor substrate 40, a P channel transistor forming region is covered with a resist (not shown in the figure), and in an N channel transistor forming region, a resist 42 is formed that has an opening only on the vicinity of the gate electrode 41. Inclination ion implantation of a P type impurity is conducted by using the resist 42 and the gate electrode 41 as a mask, so as to form a pocket layer 43 in a region right below the edge of the gate electrode 41 over the vicinity thereof.

After removing the resist 42 and forming a resist (not shown in the figure) covering the P channel transistor forming region, as shown in FIG. 5B, an N type impurity is ion-implanted at 0° to form a high concentration source/drain region 44. At this time, although the N type impurity is implanted also in a part of the pocket layer 43, the N type and P type impurities are compensated for each other in the region in which the N type impurity has been implanted, so as to form a low concentration N type region, i.e., an LDD region 45.

Also in the P channel transistor forming region, a pocket layer, a high concentration source/drain region and an LDD region are formed by using a resist in the same manner as in the foregoing.

According to the above processes for forming a semiconductor device, in any production process, because an LDD region, a pocket layer and a high concentration source/drain region are formed after forming a gate electrode, an N channel transistor forming region and a P channel transistor forming region have to be covered with a resist twice for each, and therefore four photo mask steps are required to make the production process complicate.

Particularly, in the later process, because the LDD region is formed by compensating the N type impurity and the P type impurity for each other, there is such a problem that the impurity concentration of the LDD region is difficult to control in comparison to the process where an LDD region is formed by ion implantation at a prescribed dose.

### SUMMARY OF THE INVENTION

The invention has been developed in view of the problems associated with the conventional art, and an object thereof is to provide a process for producing a semiconductor device, by which an LDD region, a pocket layer and a high concentration source/drain region can be produced by the lowest number of production steps, and to provide a semiconductor device produced by the process.

The present invention is provided with a process for producing a semiconductor device comprising the steps of:

(a) forming a gate electrode on N channel and P channel transistors forming regions on a semiconductor substrate for forming a CMOS circuit;

(b) forming a side wall spacer on a side wall of the gate electrode;

(c) covering the P channel transistor forming region with a resist, and forming a source/drain region on the N channel transistor forming region by ion implantation using the resist, the gate electrode and the side wall spacer as a mask;

(d) removing a part of the side wall spacer of the gate electrode in the N channel transistor forming region;

(e) forming an LDD region on the N channel transistor forming region by ion implantation using the resist, the gate electrode and the resulting side wall spacer as a mask;

(f) removing the resist;

(g) covering the N channel transistor forming region with a resist, and forming a source/drain region on the P channel transistor forming region by ion implantation using the resist, the gate electrode and the side wall spacer as a mask;

(h) removing a part of the side wall spacer of the gate electrode in the P channel transistor forming region; and

(i) forming an LDD region on the P channel transistor forming region by ion implantation using the resist, the gate electrode and the resulting side wall spacer as a mask

Further, the present invention is provided with a semiconductor device produced by the above process.

### BRIEF DESCRIPTION OF THE DRAWINGS

FIGS. 1A to 1E and FIGS. 2F to 2I are schematic sectional views illustrating steps of the process of manufacturing a semiconductor device in accordance with a first embodiment of the present invention;

FIGS. 3A to 3C are schematic sectional views illustrating steps of the process of manufacturing a semiconductor device in accordance with a second embodiment of the present invention;

FIGS. 4A to 4F are schematic sectional views illustrating steps of a process of manufacturing a semiconductor device in accordance with a prior art and

FIGS. 5A to 5B are schematic sectional views illustrating steps of a process of manufacturing a semiconductor device in accordance with another prior art.

### DESCRIPTION OF THE PREFERRED EMBODIMENTS

According to the process for producing a semiconductor device of the invention, a gate electrode is firstly formed on N channel and P channel transistors forming regions of a semiconductor substrate for forming a CMOS circuit in the step (a).

In general, the semiconductor substrate for forming a CMOS circuit that can be used in the invention is not particularly limited as long as a semiconductor device can be produced therewith, and examples thereof include substrates comprising an elemental semiconductor, such as silicon and germanium, and a compound semiconductor, such as GaAs and InGaAs, with a silicon substrate being preferred. The semiconductor substrate may be doped with a P type or N type impurity for being imparted with a suitable resistance, and may be doped with an impurity for adjusting the threshold value taking the characteristics of the semiconductor device to be produced, and one or plural N type or P type impurity diffusion layer (well) may be formed. Furthermore, in the semiconductor substrate, an element isolation region formed with a LOCOS film or a trench element isolation film; an element, such as a transistor, a capacitor and a resistance, and a circuit formed therewith; a dielectric film, such as an interlayer insulating film and a gate dielectric film, and a wiring layer may be formed.

The gate electrode is not particularly limited in material, as long as it is formed with an electrode material that is generally employed, and as examples thereof may be mentioned polysilicon, a metal (such as aluminum, gold, copper, silver, tungsten, tantalum, titanium, and cobalt), a silicide (such as tungsten silicide), and a laminated film thereof (such as a combination of polysilicon and tungsten silicide). The thickness of the gate electrode may be, for example, about from 100 to 500 nm. The gate electrode may be formed in such a manner that the electrode material is formed on the whole surface of the semiconductor substrate by, for example, a sputtering method, a vapor deposition method, a CVD method or an EB method, and then it is patterned to a desired shape by photolithography and an etching process.

In the step (b), a side wall spacer is formed on a side wall of the gate electrode. The side wall spacer may be formed in such a manner that a dielectric film is formed on the while surface of the semiconductor substrate including the gate electrode, and then it is subjected to etch back.

The dielectric film for forming the side wall spacer may be formed with a single layer film, such as a silicon oxide film (for example, a high temperature oxide film (an HTO film), a thermal oxidation film and a low temperature oxide film (an LTO film)) and a silicon nitride film, and is preferably formed with a laminated film thereof. Among these, it is preferably formed with a laminated film of two kinds of films that are different in material or kinds. Examples thereof include a laminated film comprising a lower layer comprising a silicon oxide film (a high temperature oxide film or a low temperature oxide film) or a silicon nitride film and an upper layer comprising a silicon oxide film (a high temperature oxide film or a low temperature oxide film), and in particular, it is preferred that the lower layer is formed with a high temperature oxide film. As the combination of the lower layer and the upper layer, such a combination is preferred that the etching rate of the upper layer is larger than that of the lower layer by a desired etching method, such as dry etching, e.g., RIE and isotropic plasma etching, and wet etching using an acid, an alkali or a mixture thereof, and such a combination is preferred that provides a selectivity ratio of the upper layer to the lower layer of about 5 or more, and more preferably about from 5 to 15. As specific examples of the combination may be mentioned a combination of an LTO film and an HTO film, a combination of an HTO film and a thermal oxidation film or a combination of an HTO film and a silicon nitride film. The thickness of the dielectric film may be, for example, about from 50 to 400 nm.

The HTO film may be formed, for example, by a reduced pressure CVD method at a growing temperature in a temperature range of about from 800 to 850° C. using SiH₄ and N₂O as a raw material gas. The LTO film may be formed at a growing temperature in a temperature range of about from 350 to 450° C. using TEOS (tetraethylorthosilicate) as a raw material gas under a pressure of about several tens Torr. The thermal oxidation film may be formed at a temperature range of about from 700 to 850° C. using NH₃ and SiH₄Cl₂ as a raw material gas under reduced pressure.

In the step (c), the P channel transistor forming region is covered with a resist, and a source/drain region is formed on the N channel transistor forming region by ion implantation using the resist, the gate electrode and the side wall spacer as a mask. The method for covering the P channel transistor forming region with the resist may be conducted by a known method, such as photolithography and an etching process.

The ion implantation may be conducted by implanting an N type impurity, such as arsenic and phosphorous, at a dose of about from 2.0×10¹⁵ to 4.0×10¹⁵ ions/cm² and an implantation energy of about from 40 to 50 keV. The ion implantation is preferably conducted in the direction of the normal line or an inclination of several degrees from the normal line of the surface of the substrate. According to the procedure, a high concentration source/drain region of about from 2.0×10²⁰ to 4.0×10²⁰ ions/cm³ can be formed only on the N channel transistor forming region.

In the step (d), a part of the side wall spacer of the gate electrode on the N channel transistor forming region is removed. The partial removal of the side wall spacer is conducted under the condition where the resist formed in the step (c) covering the P channel transistor forming region is present.

The partial removal as used herein means that the side wall spacer is not completely removed, but the thickness of the side wall spacer on the side wall of the gate electrode is reduced. The reduction in thickness is preferably conducted to remove such a thickness that corresponds to a width, by which an LDD region formed between the channel region and the high concentration source/drain region attains the function thereof. Specifically, it may be conducted by dry etching, such as isotropic plasma etching, and wet etching. Among these, a wet etching method is preferred while it depends on the kind of the film constituting the side wall spacer.

In the case as described in the foregoing where the side wall spacer comprises a laminated film having two-layer structure formed of different materials or kinds, it is preferred that the upper layer is substantially completely removed, and the lower layer is removed such that only that which is arranged on the side wall of the gate electrode remains. For example, in the case of the combination of the dielectric films described in the foregoing, wet etching using buffered HF (a mixed solution of hydrogen fluoride and ammonium fluoride) is preferred. According to the procedure, etching damage of the gate dielectric film upon partial removal of the side wall spacer can be prevented.

In the step (e), an LDD region is formed on the N channel transistor forming region by ion implantation using the resist covering the P channel transistor forming region, the gate electrode and the side wall spacer that remains after the partial removal in the step (d) as a mask.

The ion implantation may be conducted by implanting an N type impurity, such as arsenic and phosphorous, at a dose of about from 2.0×10¹³ to 6.0×10¹³ ions/cm² and an implantation energy of about from 30 to 35 keV, and is preferably conducted in the direction of the substantial normal line to the surface of the substrate.

According to the procedure, a high concentration source/drain region having an impurity concentration of about from 2.0×10¹⁸ to 6.0×10¹⁸ ions/cm³ can be formed only on the N channel transistor forming region.

In the step (f), the resist covering the P channel transistor forming region is removed. The resist can be removed by a known method, such as wet etching using a desired solution.

The steps (g) to (i) can be conducted in substantially the same manner as the steps (c) to (e) except that the ion implantation for a source/drain region of the P channel transistor is conducted by using, for example, boron or ⁴⁹BF²⁺ at a dose of about from 1.0×10¹⁵ to 3.0×10¹⁵ ions/cm² with an implantation energy of about from 30 to 40 keV, and the ion implantation for the LDD region is conducted by using, for example, boron or ⁴⁹BF²⁺ at a dose of about from 1.0×10¹³ to 3.0×10¹³ cm⁻² with an implantation energy of about from 30 to 35 keV.

Either the steps (g) to (i) or the steps (c) to (e) may be conducted first. It is preferred to remove the resist after the step (i) as similar to the step (f).

In the invention, a pocket layer may be formed between the LDD region and the channel region by ion implantation of a P type impurity in the step (e).

For example, before or after the ion implantation for the LDD region, ion implantation for a pocket layer is conducted by using boron or ⁴⁹BF²⁺ at a dose of about from 6.0×10¹² to 8.0×10¹² ions/cm² with an implantation energy of about from 50 to 60 keV at an implantation angle of from 30 to 40° from the normal line to the surface of the substrate. According to the procedure, a pocket layer having an impurity concentration of about from 6.0×10¹⁷ to 8.0×10¹⁷ ions/cm³ can be formed between the LDD region and the channel region.

In the step (i), a pocket layer may be formed in substantially the same manner as in the step (e) except that the ion implantation is conducted by using arsenic or phosphorous at a dose of about from 1.0×10¹² to 2.0×10¹² ions/cm² with an implantation energy of about from 150 to 160 keV.

In the invention, activation of the N type and P type impurity regions may be conducted before, during or after the respective steps, and steps that are generally employed for completing a semiconductor device may be arbitrary conducted that include formation of an interlayer insulating film, flattening of a dielectric film by a reflow process or CMP (chemical mechanical polishing), formation of a contact hole, and formation of wiring.

The process for producing a semiconductor device according to the invention will be described with reference to the drawings.

### EXAMPLE 1

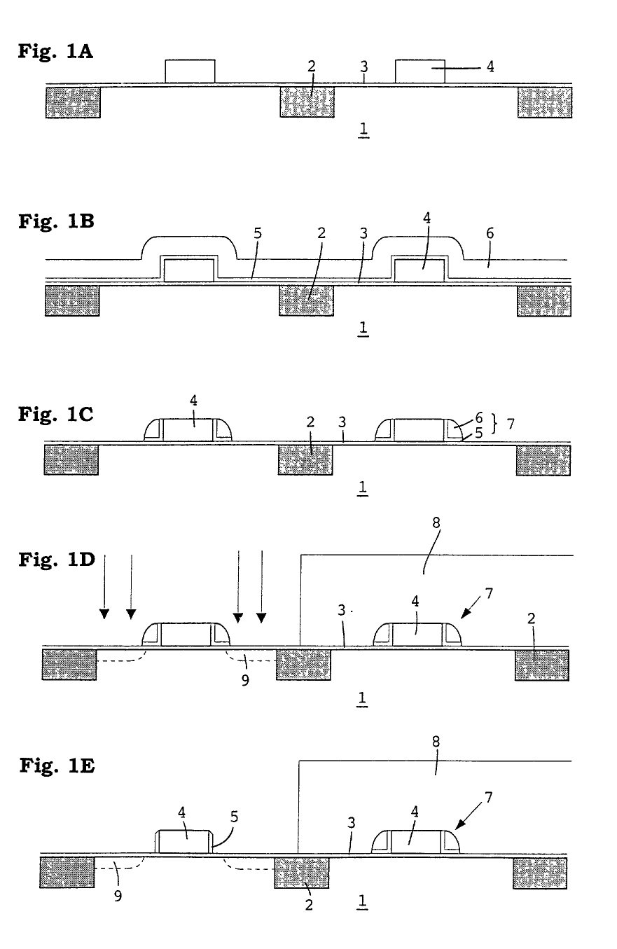

As shown in FIG. 1A, on an active region of a semiconductor substrate 1 having an element isolation region 2, after conducting ion implantation for adjusting Vth (threshold value) (for example, using ¹¹B⁺ at an implantation energy of 20 keV, a dose of 10×10¹² ions/cm² and an implantation angle of 7°), a gate dielectric film 3 having a thickness of about from 1 to 20 nm is formed. A polysilicon film is deposited thereon to a thickness of about from 100 to 200 nm, and a photo mask process is conducted to form a gate electrode 4.

As shown in FIG. 1B, a side wall lower layer film 5 becoming an etching stopper in a side wall spacer removing step described later is deposited to a thickness of about from 10 to 20 nm, and a side wall upper layer film 6 is further deposited thereon to a thickness of about from 50 to 150 nm.

As examples of the combination of the side wall upper layer film and the side wall lower layer film may be an LTO film and an HTO film. The LTO film is formed at a growing temperature of about from 350 to 400° C. using TEOS as a material gas under a pressure of about several tens Torr. The HTO film is formed by a reduced pressure CVD method at a growing temperature of about from 800 to 850° C. using SiH₄ and N₂O as a material gas.

Subsequently, as shown in FIG. 1C, the side wall upper layer film and the side wall lower layer film are subjected to etch back to form a side wall spacer 7 on the side wall of the gate electrode 4.

As shown in FIG. 1D, a P channel transistor forming region is selectively covered with a resist 8, and ion implantation of an N type impurity (for example, using ⁷⁵As⁺ at an implantation energy of from 40 to 50 keV, a dose of 2.0×10¹⁵ to 4.0×10¹⁵ ions/cm² and an implantation angle of 7°) is conducted on an N channel transistor forming region to form a high concentration source/drain 9.

Thereafter, as shown in FIG. 1E, under the condition where the resist 8 is present, the side wall spacer 7 is removed by wet etching using buffered HF with only that part of the side wall lower layer film 5 of the side wall spacer 7 which remains on the side wall of the gate electrode 4. The reason why wet etching is used for removing the side wall spacer 7 herein is that the side wall lower layer film 5 is used as an etching stopper for preventing etching damage of the gate dielectric film.

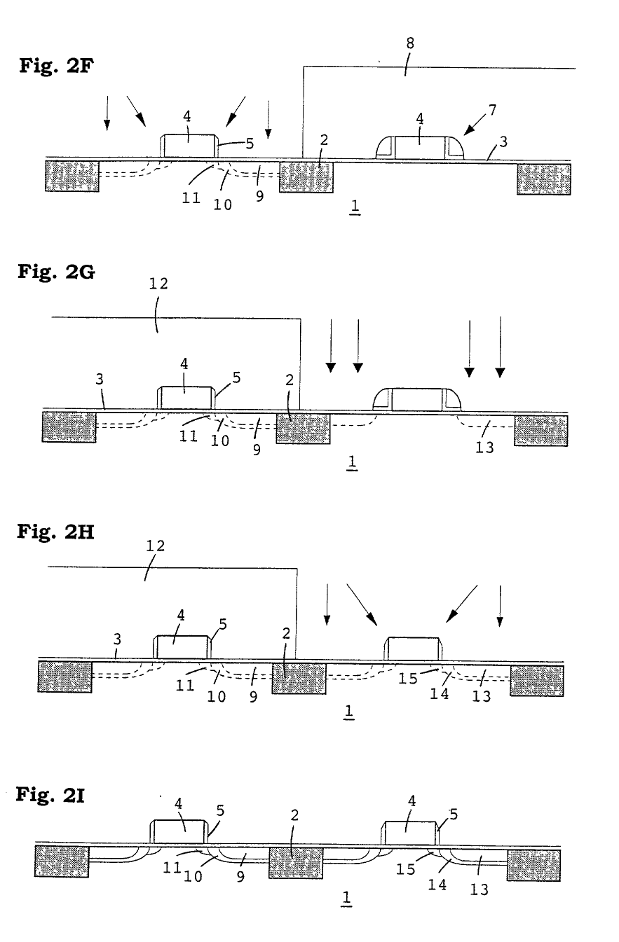

As shown in FIG. 2F, ion implantation of an N type impurity (for example, using an ³¹P⁺ at an implantation energy of from 30 to 35 keV, a dose of 2.0×10¹³ to 6.0×10¹³ ions/cm² and an implantation angle of 0°) is conducted using the resist 8, the gate electrode 4 and the side wall spacer 7 as a mask to form an LDD region 10.

Furthermore, ion implantation of a P type impurity (for example, using an ¹¹B⁺ at an implantation energy of from 50 to 60 keV, a dose of 6.0×10¹² to 8.0×10¹² ions/cm² and an implantation angle of from 30 to 40°) is conducted to form a pocket layer 11.

Thereafter, as shown in FIG. 2G, after removing the resist 8, the N channel transistor forming region is selectively covered with a resist 12, and ion implantation of a P type impurity (for example, using ⁴⁹BF²⁺ at an implantation energy of from 30 to 40 keV, a dose of 1.0×10¹⁵ to 3.0×10¹⁵ ions/cm² and an implantation angle of 7°) is conducted on the P channel transistor forming region to form a high concentration source/drain region 13.

As shown in FIG. 2H, the side wall spacer 7 is removed with only that part of the side wall lower layer film 5 of the side wall spacer 7 which remains on the side wall of the gate electrode 4 in the same manner as in the foregoing, and ion implantation of a P type impurity (for example, using ⁴⁹BF²⁺ at an implantation energy of from 30 to 35 keV, a dose of 1.0×10¹³ to 4.0×10¹³ ions/cm² and an implantation angle of 0°) is conducted to form an LDD region 14.

Furthermore, ion implantation of a P type impurity (for example, using ³¹P⁺ at an implantation energy of from 150 to 155 keV, a dose of 1.0×10¹³ to 2.0×10¹³ ions/cm² and an implantation angle of from 30 to 40°) is conducted to form a pocket layer 15.

As shown in FIG. 2I, the resist 12 is removed, and activation of the N type and P type impurities implanted regions is conducted by a thermal treatment.

Furthermore, an SiO₂ film containing boron and phosphorous is deposited as an interlayer insulating film to a thickness of about from 600 to 900 nm by a CVD method, which is flattened by a CMP method, and a contact hole and a wiring pattern are formed, so as to complete the semiconductor device.

According to the example, a photo process is conducted only once for covering each of the P channel and N channel transistors forming regions for forming the source/drain region, the LDD region and the pocket layer of the transistor. Therefore, the number of steps of the process can be cut down to reduce the production cost, and, at the same time, the turn around time (TAT) can be shortened. Moreover, reduction in yield and deterioration in characteristics of the device caused by the photo process can be prevented by cutting down the photo process.

### EXAMPLE 2

According to the same procedures as in FIGS. 1A to 1E, a gate electrode 4 is formed on a semiconductor substrate 1, and a side wall spacer formed with a side wall lower layer film 5 and a high concentration source/drain region 9 are formed on an N channel transistor forming region.

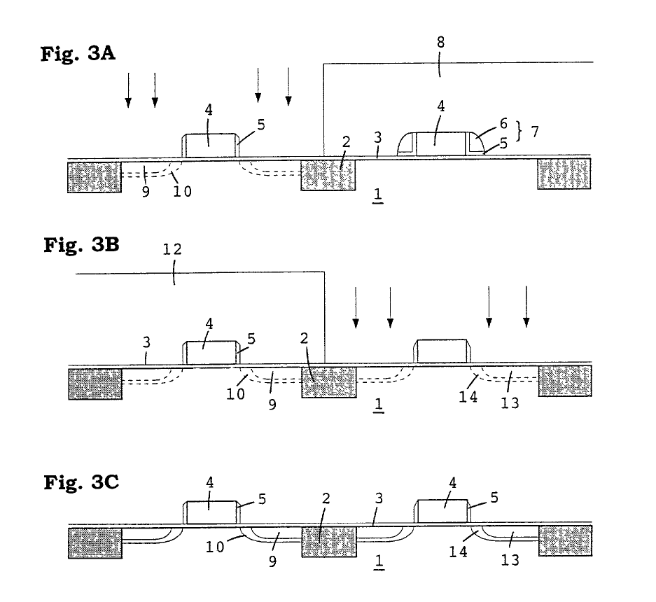

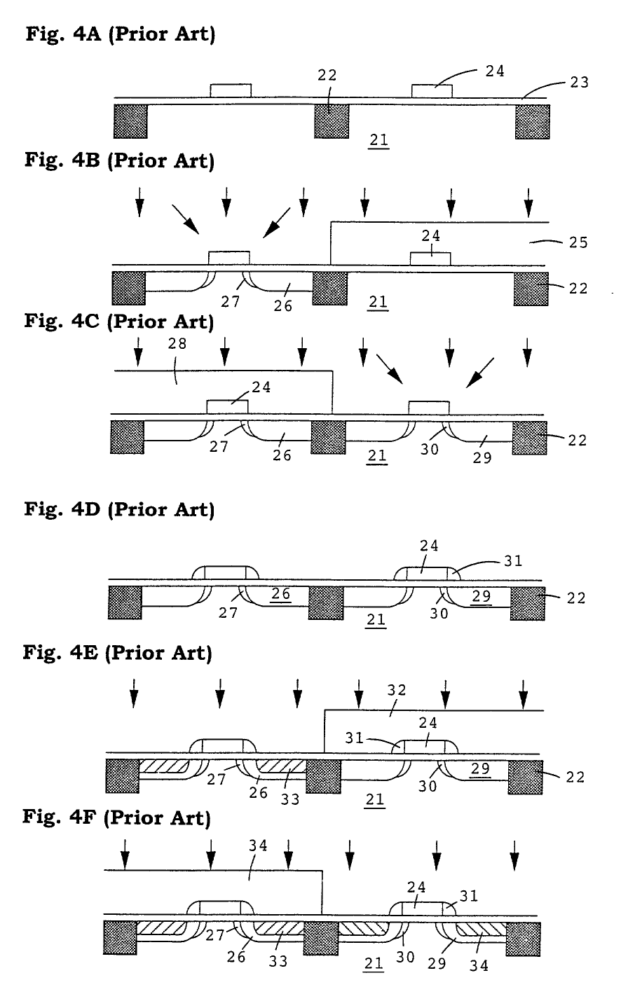

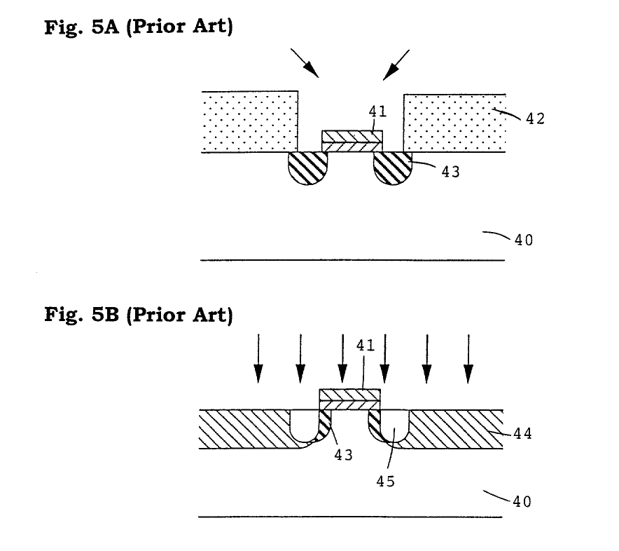

Thereafter, as shown in FIG. 3A, ion implantation of an N type impurity (for example, using ³¹P⁺ at an implantation energy of from 30 to 35 keV, a dose of 2.0×10¹³ to 6.0×10¹³ ions/cm² and an implantation angle of 0°) is conducted to form an LDD region 10.

As shown in FIG. 3B, after removing the resist 8, the N channel transistor forming region is covered with a resist 12, and a high concentration source/drain region 13 and an LDD region 14 are formed on a P channel transistor forming region in the same manner.

As shown in FIG. 3C, the resist 12 is removed, and activation of the N type and P type impurities implanted regions is conducted by a thermal treatment.

Thereafter, an interlayer dielectric film, a contact hole and a wiring pattern are formed in the same manner as in the foregoing, so as to complete the semiconductor device.

According to the example, a photo process is conducted only once for covering each of the P channel and N channel transistors forming regions for forming the source/drain region and the LDD region of the transistor. Therefore, the number of steps of the process can be cut down to reduce the production cost, and, at the same time, the turn around time (TAT) can be shortened. Moreover, reduction in yield and deterioration in characteristics of the device caused by the photo process can be prevented by cutting down the photo process.

According to the invention, a source/drain region and an LDD region of a transistor can be formed by conducting a photo process for covering each of P channel and N channel transistors forming regions only once. Therefore, the number of steps of the process can be cut down to reduce the production cost, and, at the same time, the turn around time (TAT) can be shortened. Moreover, reduction in yield and deterioration in characteristics of the device caused by the photo process can be prevented by reducing the photo process.

In the case where ion implantation of a P type impurity is further conducted in the step (e) to form a pocket layer between an LDD region and a channel region, and ion implantation of an N type impurity is further conducted in the step (i) to form a pocket layer between an LDD region and a channel region, a source/drain region, an LDD region and a pocket layer of a transistor can be formed by conducting a photo process for covering each of P channel and N channel transistors forming regions only once, and therefore reduction of the production cost and shortening of the TAT can be realized as similar to the foregoing.

Furthermore, in the case where the side wall spacer is formed by a deposited film of a lower layer film comprising a high temperature oxide film, a thermal oxidation film or a silicon nitride film, and a upper layer film comprising a high temperature oxide film or a low temperature oxide film, and particularly in the case where a part of the side wall spacer is removed by substantially completely removing the upper layer film by a wet etching method with a selectivity ratio of the upper layer film to the lower layer film of from 5 to 15, damage of the gate dielectric film can be suppressed to the minimum, so as to prevent reduction in yield and deterioration in characteristics of the device.

According to the invention, a semiconductor device having high reliability and low production cost can also be provided.

What is claimed is:

1. A process for producing a semiconductor device comprising the steps of:
(a) forming a gate electrode on N channel and P channel transistors forming regions on a semiconductor substrate for forming a CMOS circuit;
(b) forming a side wall spacer on a side wall of the gate electrode;
(c) covering the P channel transistor forming region with a resist, and forming a source/drain region on the N channel transistor forming region by ion implantation using the resist, the gate electrode and the side wall spacer as a mask;
(d) removing a part of the side wall spacer of the gate electrode in the N channel transistor forming region;
(e) forming an LDD region on the N channel transistor forming region by ion implantation using the resist, the gate electrode and the resulting side wall spacer as a mask;
(f) removing the resist;
(g) covering the N channel transistor forming region with a resist, and forming a source/drain region on the P channel transistor forming region by ion implantation using the resist, the gate electrode and the side wall spacer as a mask;
(h) removing a part of the side wall spacer of the gate electrode in the P channel transistor forming region; and
(i) forming an LDD region on the P channel transistor forming region by ion implantation using the resist, the gate electrode and the resulting side wall spacer as a mask.

2. A process for producing a semiconductor device as claimed in claim 1, wherein
in the step (e), a P type impurity is ion-implanted to form a pocket layer between the LDD region and the channel region; and
in the step (i), an N type impurity is ion-implanted to form a pocket layer between the LDD region and the channel region.

3. A process for producing a semiconductor device as claimed in claim 1 or 2, wherein in the step (b), the side wall spacer is formed with a deposited film comprising an upper layer film and a lower layer film comprising materials or kinds different from each other.

4. A process for producing a semiconductor device as claimed in claim 3, wherein the lower layer film comprises a high temperature oxide film, a thermal oxidation film or a silicon oxide film, and the upper layer film comprises a high temperature oxide film or a low temperature oxide film.

5. A process for producing a semiconductor device as claimed in claim 3 or 4, wherein in the steps (d) and (h), the upper layer film is substantially completely removed by a wet etching method having a selective ratio of the upper layer film to the lower layer film of from 5 to 15, whereby a part of the side wall spacer is removed.

6. A semiconductor device produced by a process claimed in any of claims 1 to 5.
